(19) United States
(12) Patent Application Publication
(10) Pub. No.: US 2026/0090201 A1
(43) Pub. Date: Mar. 26, 2026

(54) APPARATUS FOR MANUFACTURING DISPLAY DEVICE AND METHOD OF MANUFACTURING DISPLAY DEVICE USING THE SAME

(71) Applicant: SAMSUNG DISPLAY CO., LTD., Yongin-si (KR)

(72) Inventors: Gyuseong SHIM, Yongin-si (KR); SANG KIL WOO, Yongin-si (KR); CHANG HYUNG LEE, Yongin-si (KR)

(21) Appl. No.: 19/318,142

(22) Filed: Sep. 3, 2025

(30) Foreign Application Priority Data
Sep. 24, 2024 (KR) 10-2024-0128995

(51) Int. Cl. H10K 59/12; H10K 59/80; H10K 59/88; H10K 102/00

(52) U.S. Cl. CPC H10K 59/1201; H10K 59/872; H10K 59/88; H10K 2102/311

(57) ABSTRACT

An apparatus for manufacturing a display device and a method of manufacturing a display device using the same are disclosed. An apparatus for manufacturing a display device includes a lower jig, an upper jig above the lower jig and including a bottom surface facing the lower jig and on which a window is arranged, and a camera between the lower jig and the upper jig. The lower jig includes a first lower jig on which a display panel including a main mark is configured to be arranged, a second lower jig under the first lower jig and including an alignment mark, and a driver between the first lower jig and the second lower jig.

### CROSS-REFERENCE TO RELATED APPLICATION

The present application claims priority to and the benefit of Korean Patent Application No. 10-2024-0128995, filed on Sep. 24, 2024 in the Korean Intellectual Property Office, the entire disclosure of which is incorporated herein by reference.

### BACKGROUND

### 1. Field

Aspects of embodiments of the present disclosure relate to an apparatus for manufacturing a display device and a method of manufacturing a display device using the same.

### 2. Description of Related Art

An electronic apparatus, such as a smartphone, a digital camera, a laptop computer, a navigation system, or a smart television, for providing an image to a user may include a display device for displaying an image. Generally, the display device may include a display panel for displaying an image and a window disposed on the display panel to protect a front surface of the display panel.

The window may be attached to the display panel by an optical clear adhesive. However, when the window is attached to the display panel, the window may not be attached to the display panel at a correct position due to various factors. Thus, technology that enables the window and the display panel to be more precisely aligned is required.

### SUMMARY

According to aspects of embodiments of the present disclosure, an apparatus for manufacturing a display device which can improve alignment precision of a display panel and a window, and a method of manufacturing a display device using the same, are provided.

According to one or more embodiments of the present disclosure, an apparatus for manufacturing a display device includes: a lower jig; an upper jig above the lower jig, and including a bottom surface facing the lower jig and on which a window is arranged; and a camera, or camera part, between the lower jig and the upper jig, wherein the lower jig includes a first lower jig on which a display panel including a main mark is located, a second lower jig under the first lower jig and including an alignment mark, and a driver, or driving part, between the first lower jig and the second lower jig.

In one or more embodiments of the present disclosure, a method of manufacturing a display device includes arranging a display panel including a main mark on a first lower jig parallel to a plane defined by a first direction and a second direction crossing the first direction, and arranging a window on a bottom surface of an upper jig located above the first lower jig, aligning the main mark of the display panel and an alignment mark of a second lower jig located under the first lower jig by rotating the first lower jig about a rotation axis parallel to a third direction crossing a plane defined by the first direction and the second direction, molding the display panel by applying an external force to the display panel such that a top surface of the display panel has a curved surface that is concave downward, aligning the alignment mark and a deformation mark defined by the main mark of the molded display panel by rotating the first lower jig, acquiring position information about the window and position information about the alignment mark, and aligning the window and the display panel, and moving the window downward toward the display panel, and bonding the window and the display panel.

### BRIEF DESCRIPTION OF THE DRAWINGS

The accompanying drawings are included to provide a further understanding of the present disclosure, and are incorporated in and constitute a part of this specification. The drawings illustrate some embodiments of the inventive concept and, together with the description, serve to explain principles of the inventive concept. In the drawings:

FIG. 1A is a perspective view of a display device according to an embodiment of the present disclosure;

FIG. 1B is a perspective view illustrating that the display device illustrated in FIG. 1A is unfolded in a flat state;

FIG. 2 schematically illustrates a cross-section of the display device illustrated in FIG. 1B;

FIG. 3 is a plan view of a display panel illustrated in FIG. 2;

FIG. 4A is a cross-sectional view taken along the line I-I′ illustrated in FIG. 3;

FIG. 4B illustrates a bent state of a bending region illustrated in FIG. 4A;

FIG. 5 schematically illustrates a cross-section of a pixel and a main mark illustrated in FIG. 3;

FIG. 6 is a perspective view of a main mark illustrated in FIG. 5;

FIG. 7 is a plan view of a window illustrated in FIG. 2;

FIG. 8 is a flowchart for illustrating a method of manufacturing a display device according to an embodiment of the present disclosure;

FIGS. 9A to 9D are side views illustrating a method of manufacturing a display device according to an embodiment of the present disclosure;

FIG. 10 is a plan view of a first lower jig and a second lower jig illustrated in FIG. 9A;

FIG. 11 is a flowchart for illustrating an alignment between a display panel and a second lower jig according to an embodiment of the present disclosure;

FIGS. 12A and 12B are plan views illustrating an alignment between a display panel and a second lower jig;

FIGS. 13A and 13B illustrate an alignment between a molded display panel and a second lower jig; and

FIG. 14 is a plan view illustrating an alignment of a window.

### DETAILED DESCRIPTION

In this specification, it is to be understood that when an element (or a region, a layer, a portion, or the like) is referred to as being “on,” “connected to,” or “coupled to” another element, it may be directly disposed on/connected to/coupled to the other element or layer or one or more intervening elements may be disposed therebetween.

Like reference numerals or symbols refer to like elements throughout. Also, in the drawings, the thicknesses, ratios, and dimensions of the elements are exaggerated for effective description of the technical contents. The term “and/or” includes all of one or more combinations which can be defined by related elements.

Although the terms “first,” “second,” etc. may be used to describe various elements, these elements are not to be limited by these terms. These terms are used to distinguish one element from another element. For example, a first element may be referred to as a second element, and, similarly, a second element may also be referred to as a first element without departing from the scope of the present disclosure. The singular forms include the plural forms as well, unless the context clearly indicates otherwise.

Also, terms of “below,” “on a lower side,” “above,” “on an upper side,” or the like may be used to describe the relationships of the elements illustrated in the drawings. These terms have relative concepts and are described on the basis of the directions indicated in the drawings.

It is to be understood that the terms “includes” or “comprises,” when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skills in the art to which the present disclosure belongs. Also, terms, such as those defined in commonly used dictionaries, are to be interpreted as having a meaning that is consistent with their meaning in the context of the relevant art and are not to be interpreted in an idealized or overly formal sense unless expressly so defined herein.

Herein, embodiments of the present disclosure will be described with reference to the accompanying drawings.

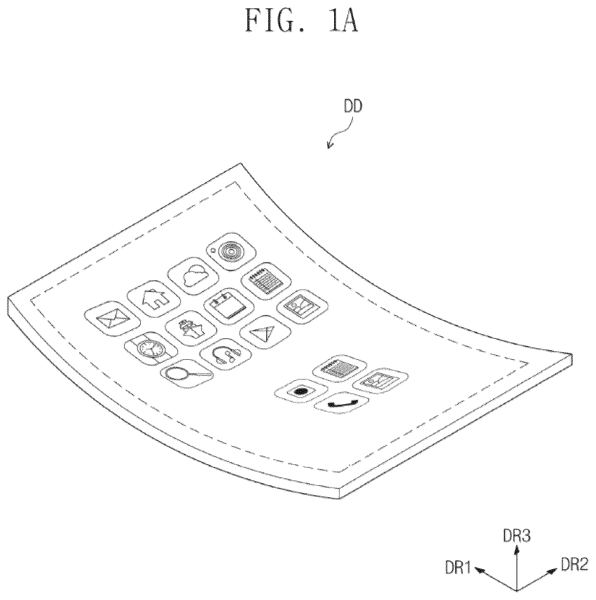

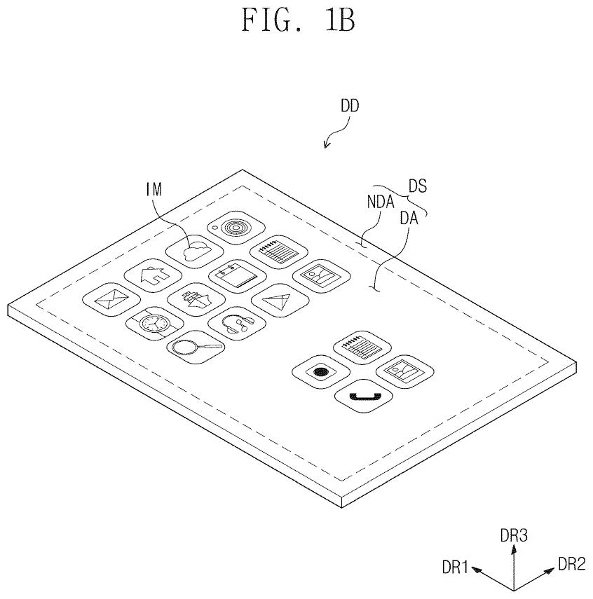

FIG. 1A is a perspective view of a display device according to an embodiment of the present disclosure; and FIG. 1B is a perspective view illustrating that the display device illustrated in FIG. 1A is unfolded in a flat state.

Referring to FIG. 1A, a display device DD according to an embodiment of the inventive concept may be curved concavely downward. A top surface of the display device DD may have a curved surface that is concave downward.

Herein, for the convenience of explanation, as illustrated in FIG. 1B, the description will be focused on a case in which the display device DD is unfolded in a flat state.

Referring to FIG. 1B, in an embodiment, when the display device DD is unfolded in a flat state, the display device DD may have a rectangular shape having long sides extending in a first direction DR1 and short sides extending in a second direction DR2 crossing the first direction DR1. However, a shape of the display device DD is not limited thereto, and the display device DD may have any of various shapes, such as a circular or a polygonal shape.

Herein, a direction crossing substantially perpendicularly to a plane defined by the first direction DR1 and the second direction DR2 is defined as a third direction DR3. Also, in this specification, the terms “when seen on a plane” or “as viewed on a plane” may indicate a state seen from the third direction DR3.

The top surface of the display device DD may be defined as a display surface DS and may have a plane defined by the first direction DR1 and the second direction DR2. Images IM generated from the display device DD through the display surface DS may be provided to a user.

The display surface DS may include a display region DA and a non-display region NDA around the display region DA. The display region DA may display an image, and the non-display region NDA may not display an image. In an embodiment, the non-display region NDA may surround the display region DA, and may define a border of the display device DD printed in a color (e.g., a predetermined color).

In an embodiment, the display device DD may be used in a large-sized electronic apparatus, such as a television, a monitor, or an external billboard. Also, the display device DD may be used in a small- or medium-sized electronic apparatus, such as a personal computer, a laptop computer, a personal digital terminal, a car navigation unit, a game console, a smartphone, a tablet computer, or a camera. However, these are provided only as examples, and the display device DD may be used in other electronic apparatuses without departing from the inventive concept.

It is illustrated in the above that the display device DD is unfolded in a flat state parallel to the first direction DR1 and the second direction DR2, but the display device DD may have a curved shape that is concave downward with respect to an axis parallel to the second direction DR2, as illustrated in FIG. 1A.

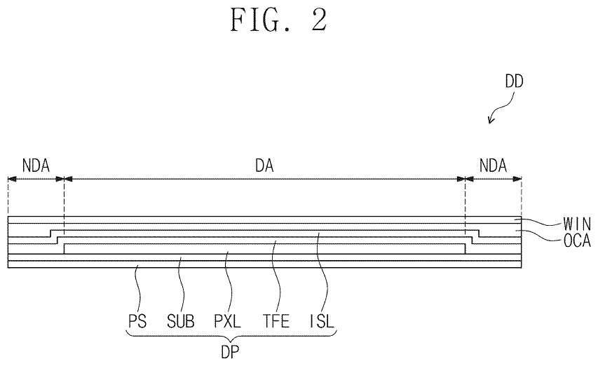

FIG. 2 schematically illustrates a cross section of the display device illustrated in FIG. 1B.

For convenience of explanation, it is illustrated that the display device DD in FIG. 2 is unfolded in a flat state, but the display device DD may generally have a curved shape when seen from the second direction DR2, as illustrated in FIG. 1A.

Among components illustrated in FIG. 2, descriptions of the components that are the same as the components explained with reference to the drawings may be omitted or explained briefly.

Referring to FIG. 2, the display device DD may include a display panel DP, a window WIN disposed above the display panel DP, and an adhesive OCA disposed between the display panel DP and the window WIN.

The display panel DP according to an embodiment may be a light-emitting display panel, but is not particularly limited. For example, the display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include any of quantum dots, quantum rods, and the like. Herein, the display panel DP will be described as an organic light-emitting display panel.

In an embodiment, the display panel DP may include a substrate SUB, a pixel layer PXL disposed on the substrate SUB, a thin-film encapsulation layer TFE disposed on the substrate SUB to cover the pixel layer PXL, an input sensing layer ISL disposed on the thin-film encapsulation layer TFE, and a protective substrate PS disposed under the substrate SUB.

The substrate SUB may be a transparent substrate and include a flexible plastic substrate. In an embodiment, for example, the substrate SUB may include polyimide (PI). The substrate SUB may include a display region DA and a non-display region NDA around the display region DA. The pixel layer PXL may be disposed in the display region DA. The pixel layer PXL may include a plurality of pixels, and each of the pixels may include a light-emitting element.

In an embodiment, the thin-film encapsulation layer TFE may include at least two inorganic layers and an organic layer disposed between the inorganic layers. The inorganic layers may include an inorganic material and may protect the pixel layer PXL from moisture/oxygen. The organic layer may include an organic material and may protect the pixel layer PXL from foreign matter, such as dust particles.

The input sensing layer ISL may sense an external input (for example, a user's touch). The input sensing layer ISL may include a plurality of sensors (not illustrated) for sensing an external input. In an embodiment, the sensors may sense an external input in a capacitive manner. The display panel DP may generate an image corresponding to the external input sensed by the input sensing layer ISL. The input sensing layer ISL may be produced directly on the thin-film encapsulation layer TFE.

The protective substrate PS may protect a lower portion of the substrate SUB. The protective substrate PS may include a flexible plastic substrate. In an embodiment, for example, the protective substrate PS may include polyethylene terephthalate (PET).

The window WIN may protect the display panel DP from an external scratch and/or impact. The window WIN may be attached to the display panel DP by the adhesive OCA. In an embodiment, the adhesive OCA may include an optical clear adhesive. An image generated from the display panel DP may be provided to a user through the window WIN.

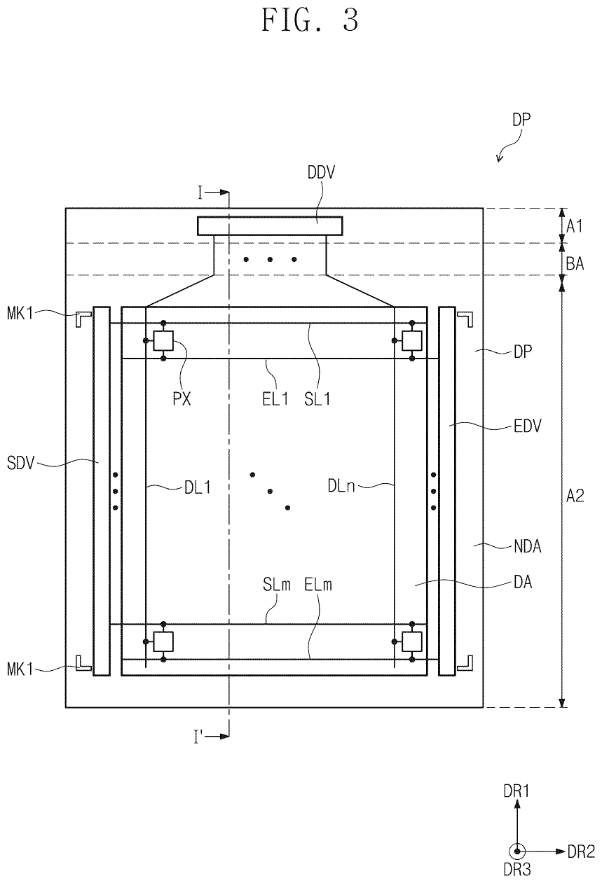

FIG. 3 is a plan view of the display panel illustrated in FIG. 2.

Referring to FIG. 3, a display device DD according to an embodiment of the inventive concept may include a display panel DP, a scan driver SDV, a data driver DDV, and an emission driver EDV.

The display panel DP may be a flexible display panel. For example, the display panel DP may include a plurality of electronic elements disposed on a flexible substrate. In an embodiment, the display panel DP may have a rectangular shape having long sides extending in the first direction DR1 and short sides extending in the second direction DR2.

In an embodiment, the display panel DP may include a first region A1, a second region A2, and a bending region BA between the first region A1 and the second region A2. The bending region BA may extend in the second direction DR2, and the first region A1, the bending region BA, and the second region A2 may be arranged in the first direction DR1.

The second region A2 may include a display region DA and a non-display region NDA around the display region DA. In an embodiment, the non-display region NDA may surround the display region DA. The display region DA may display an image, and the non-display region NDA may not display an image. In an embodiment, the first region A1 and the bending region BA may not display an image. A region in which an image is not displayed may be defined as a bezel region.

The display panel DP may include a plurality of pixels PX, a plurality of scan lines SL1-SLm, a plurality of data lines DL1-DLn, and a plurality of emission lines EL1-Elm, where m and n are natural numbers. The pixels PX may be arranged in a matrix form, but an arrangement is not limited thereto, and the pixels PX may be arranged in any of various forms. The pixels PX may be disposed in the display region DA, and may be connected to the scan lines SL1-SLm, the data lines DL1-DLn, and the emission lines EL1-ELm.

The scan driver SDV and the emission driver EDV may be disposed in the non-display region NDA, and the data driver DDV may be disposed in the first region A1. The scan driver SDV and the emission driver EDV may be disposed in the non-display region NDA adjacent to each of the long sides of the display panel DP. In an embodiment, the data driver DDV may be in an integrated circuit chip form and disposed in the first region A1.

The scan lines SL1-SLm may extend in the second direction DR2 and be connected to the scan driver SDV. The data lines DL1-DLn may extend in the first direction DR1, and be connected to the data driver DDV via the bending region BA. The emission lines EL1-ELm may extend in the second direction DR2 and be connected to the emission driver EDV.

The scan driver SDV may generate a plurality of scan signals, and the scan signals may be applied to the pixels PX through the scan lines SL1-SLm. The scan signals may be applied to the pixels PX sequentially. The data driver DDV may generate a plurality of data voltages, and the data voltages may be applied to the pixels PX through the data lines DL1-DLn. The emission driver EDV may generate a plurality of emission signals, and the emission signals may be applied to the pixels PX through the emission lines EL1-ELm.

In an embodiment, although not illustrated, the display device DD may include a timing controller (not illustrated) for controlling operations of the scan driver SDV, the data driver DDV, and the emission driver EDV.

The timing controller may generate a scan control signal, a data control signal, and an emission control signal in response to control signals received from the outside. The timing controller may receive image signals from the outside, convert the data format of the image signals to meet the interface specifications with the data driver DDV, and provide the image signals to the data driver DDV.

The scan driver SDV may generate scan signals in response to the scan control signal, and the emission driver EDV may generate emission signals in response to the emission control signal. The data driver DDV may receive the image signals having the data format converted, and may generate data voltages corresponding to the image signals in response to the data control signal.

The pixels PX may receive the data voltages in response to the scan signals. The pixels PX may display an image by emitting light with a brightness corresponding to the data voltages in response to the emission signals. An emission time of the pixels PX may be controlled by the emission signals.

The display panel DP may include a plurality of main marks MK1. The main marks MK1 may be disposed in the non-display region NDA. In an embodiment, two pairs of main marks MK1 may be disposed in the second direction DR2 with the display region DA therebetween, and one pair of main marks MK1 may be spaced apart from each other in the first direction DR1. However, positions of the main marks MK1 are not limited thereto.

In an embodiment, the main marks MK1 may have an “L” shape, but a shape of the main marks MK1 is not limited thereto.

When viewed on a plane, the main marks MK1 may be disposed so as not to overlap the data lines DL1-DLn. As an example, the main marks MK1 may be disposed to be adjacent to the corners of the display region DA, but arrangement positions of the main marks MK1 are not limited thereto.

As an example, four main marks MK1 may be disposed in the non-display region NDA, but a number of the main marks MK1 is not limited thereto. A function of the main marks MK1 will be explained in further detail later in a description of a method of manufacturing a display device DD according to an embodiment of the present disclosure.

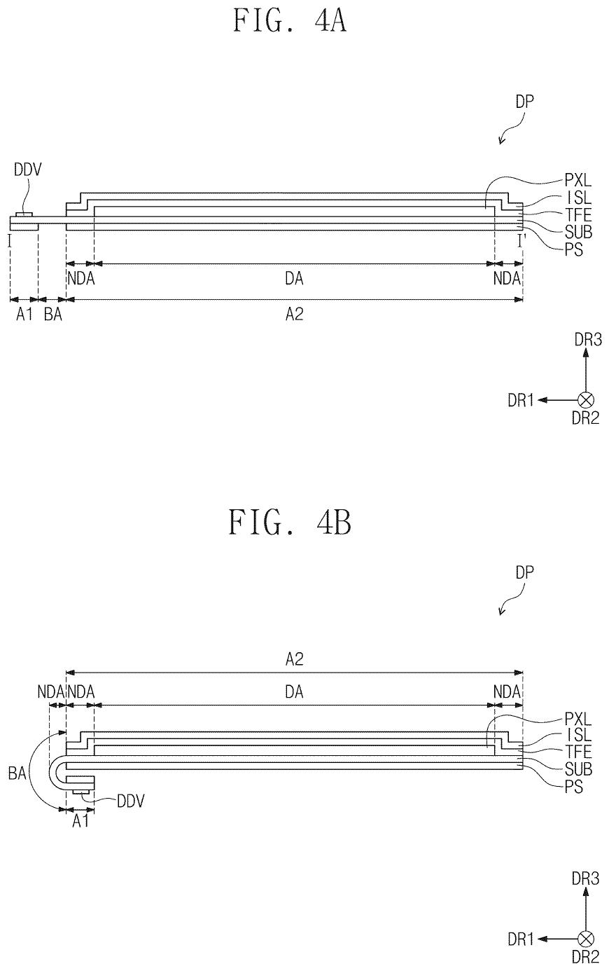

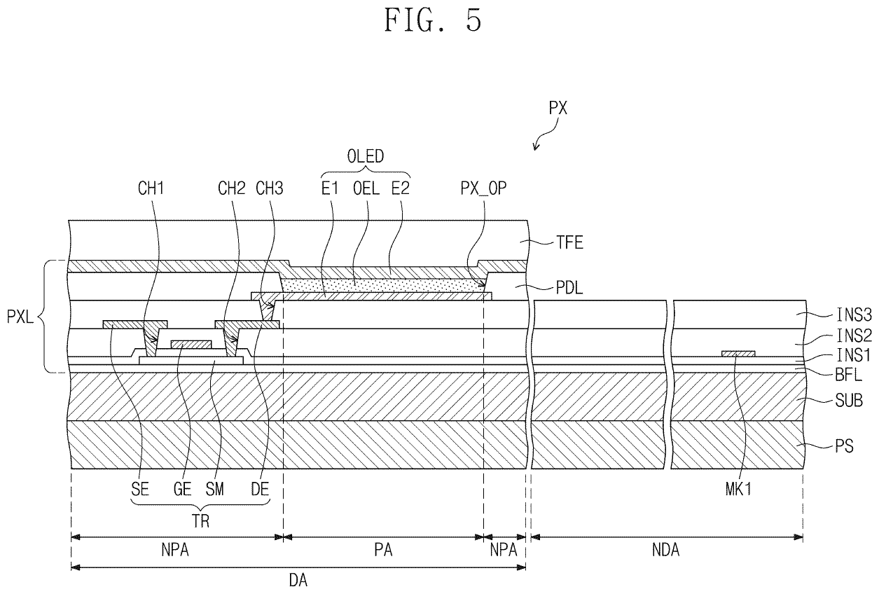

FIG. 4A is a cross-sectional view taken along the line I-I′ illustrated in FIG. 3; and FIG. 4B illustrates a bent state of a bending region illustrated in FIG. 4A.

For convenience of explanation, it is illustrated that the display panel DP in FIG. 4A and FIG. 4B is unfolded in a flat state, but, similarly to the display device DD illustrated in FIG. 1A, the display panel DP may generally have a curved shape that is concave downward.

Among components illustrated in FIGS. 4A to 4B, description of the components that are the same as the components explained with reference to the previous drawings may be omitted or explained briefly.

Referring to FIG. 4A, as described above, the protective substrate PS may be disposed under the substrate SUB, and the pixel layer PXL, the thin-film encapsulation layer TFE, and the input sensing layer ISL may be disposed on the substrate SUB. The data driver DDV may be disposed on the substrate SUB in the first region A1.

The protective substrate PS may be disposed under the substrate SUB in the first region A1 and the second region A2, and may not be disposed under the substrate SUB in the bending region BA. In an embodiment, after the protective substrate PS is disposed under the substrate SUB, a portion of the protective substrate PS overlapping the bending region BA may be removed.

Referring to FIG. 4B, the bending region BA may be bent toward the bottom of the display panel DP. The bending region BA may be bent such that the first region A1 may be disposed under the second region A2. Therefore, the data driver DDV may be disposed under the display panel DP. As the first region A1 is disposed under the rear surface of the second region A2, the bezel region of the display panel DP may be minimized or reduced when viewed on a plane.

As the protective substrate PS is not disposed in the bending region BA, the thickness of the bending region BA of the display device DD is reduced, and the bending region BA may bend more easily. When viewed on a plane, the bending region BA exposed to the outside may be defined as a non-display region NDA.

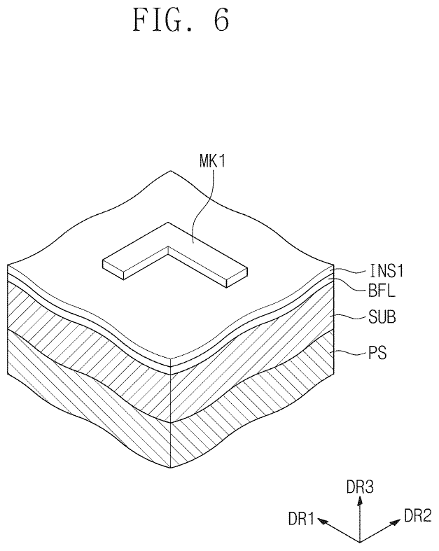

FIG. 5 schematically illustrates a cross section of any one pixel and a main mark illustrated in FIG. 3. FIG. 6 is a perspective view of a main mark illustrated in FIG. 5.

Referring to FIG. 5, a pixel PX may include a light-emitting element OLED and a transistor TR connected to the light-emitting element OLED. The light-emitting element OLED may include a first electrode E1, a second electrode E2, and an organic light-emitting layer OEL disposed between the first electrode E1 and the second electrode E2.

In an embodiment, the first electrode E1 may be an anode electrode, and the second electrode E2 may be a cathode electrode. The first electrode E1 may be defined as a pixel electrode, and the second electrode E2 may be defined as a common electrode.

The pixel PX may be divided into a pixel region PA and a non-pixel region NPA around the pixel region PA. The light-emitting element OLED may be disposed in the pixel region PA, and the transistor TR may be disposed in the non-pixel region NPA.

The transistor TR and the light-emitting element OLED may be disposed on the substrate SUB. In an embodiment, a buffer layer BFL may be disposed on the substrate SUB, and the buffer layer BFL may include an inorganic material.

A semiconductor layer SM of the transistor TR may be disposed on the buffer layer BFL. The semiconductor layer SM may include an organic semiconductor or a semiconductor made of an inorganic material, such as amorphous silicon or polysilicon. In an embodiment, the semiconductor layer SM may include an oxide semiconductor. Although not illustrated in FIG. 5, the semiconductor layer SM may include a source region, a drain region, and a channel region between the source region and the drain region.

A first insulation layer INS1 may be disposed on the buffer layer BFL to cover the semiconductor layer SM. In an embodiment, the first insulation layer INS1 may include an inorganic material. A gate electrode GE of the transistor TR overlapping the semiconductor layer SM may be disposed on the first insulation layer INS1. The gate electrode GE may be disposed so as to overlap the channel region of the semiconductor layer SM.

A second insulation layer INS2 may be disposed on the first insulation layer INS1 to cover the gate electrode GE. The second insulation layer INS2 may include an organic material and/or an inorganic material. A source electrode SE and a drain electrode DE of the transistor TR may be disposed on the second insulation layer INS2 and spaced apart from each other. The gate electrode GE, the source electrode SE, and the drain electrode DE may include a metal.

The source electrode SE may be connected to the source region of the semiconductor layer SM through a first contact hole CH1 defined in the first insulation layer INS1 and the second insulation layer INS2. The drain electrode DE may be connected to the drain region of the semiconductor layer SM through a second contact hole CH2 defined in the first insulation layer INS1 and the second insulation layer INS2.

A third insulation layer INS3 may be disposed on the second insulation layer INS2 to cover the source electrode SE and the drain electrode DE of the transistor TR. In an embodiment, the third insulation layer INS3 may be defined as a planarization film for providing a flat top surface, and may include an organic material.

The first electrode E1 may be disposed on the third insulation layer INS3. The first electrode E1 may be connected to the drain electrode DE of the transistor TR through a third contact hole CH3 defined in the third insulation layer INS3.

A pixel-defining film PDL exposing a portion (e.g., a predetermined portion) of the first electrode E1 may be disposed on the first electrode E1 and the third insulation layer INS3. An opening PX_OP for exposing a portion (e.g., a predetermined portion) of the first electrode E1 may be defined in the pixel-defining film PDL.

The organic light-emitting layer OEL may be disposed on the first electrode E1 inside the opening PX_OP. The organic light-emitting layer OEL may generate any of red, green, or blue light. However, colors of the light are not limited thereto, and, in an embodiment, the organic light-emitting layer OEL may generate white light through a combination of the organic materials which produce the colors red, green, and blue.

The second electrode E2 may be disposed on the pixel-defining film PDL and the organic light-emitting layer OEL. A thin-film encapsulation layer TFE may be disposed on the light-emitting element OLED to cover the pixel PX. The layers between the substrate SUB and the thin-film encapsulation layer TFE may be defined as a pixel layer PXL.

A first voltage may be applied to the first electrode E1, and a second voltage may be applied to the second electrode E2. Holes and electrons injected to the organic light-emitting layer OEL are combined to form excitons, and the light-emitting element OLED may emit light as the excitons transit to a ground state. The light-emitting element OLED may emit red light, green light, and blue light in response to a flow of current, and thus an image may be displayed.

A main mark MK1 may be disposed on the first insulation layer INS1. In an embodiment, the main mark MK1 and the gate electrode GE may be made of a same material and formed concurrently (e.g., simultaneously) through patterning. In an embodiment, the main mark MK1 and the gate electrode GE may be disposed on a same layer.

Referring the FIG. 6, in an embodiment, the main mark MK1 may be formed in an embossed form. However, a form is not limited thereto, and, in an embodiment, the main mark MK1 may be formed in an engraved form.

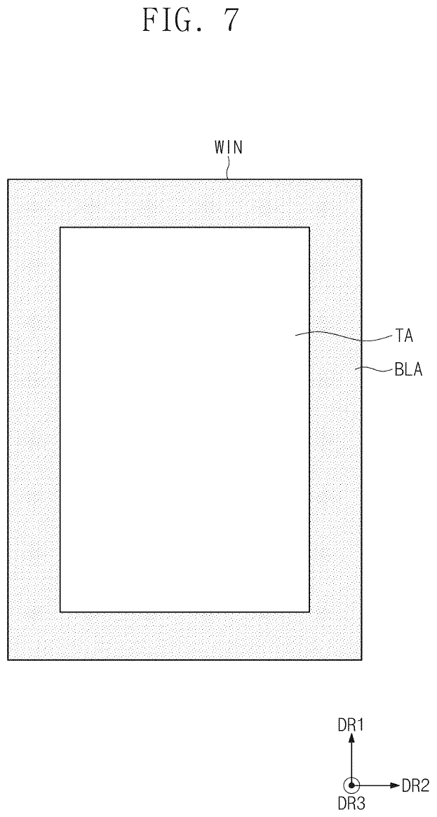

FIG. 7 is a plan view of a window illustrated in FIG. 2.

For convenience of explanation, FIG. 7 illustrates a window WIN unfolded in a flat state, but, similarly to the display device DD illustrated in FIG. 1A, the window WIN may have a curved shape that is concave downward.

Referring to FIG. 7, in an embodiment, the window WIN may have a rectangular shape having long sides in the first direction DR1 and short sides in the second direction DR2. The window WIN may include a transmission region TA and a light blocking region BLA around the transmission region TA. As an example, when viewed on a plane, the light blocking region BLA may surround the transmission region TA. The transmission region TA may allow light to pass therethrough, and the light blocking region BLA may block light.

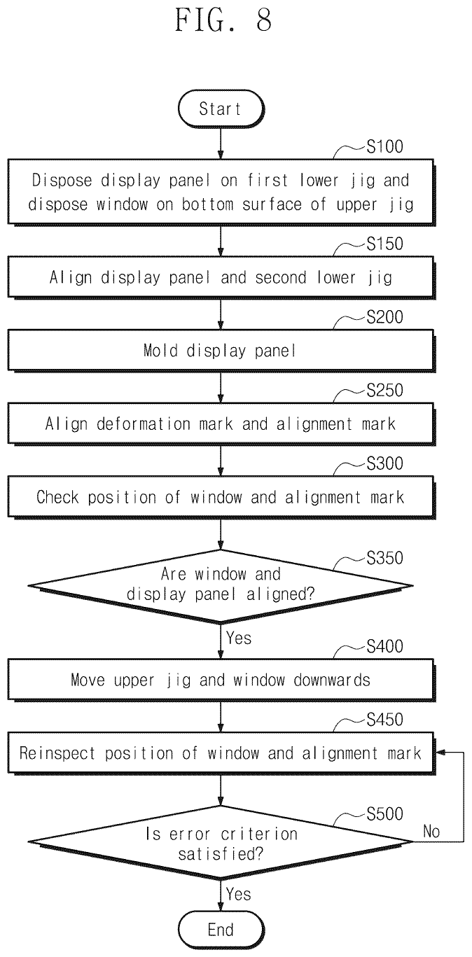

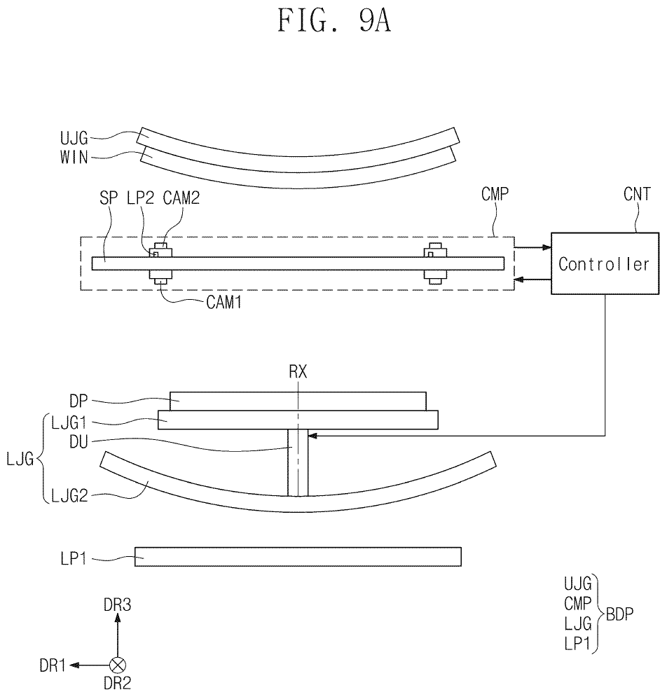

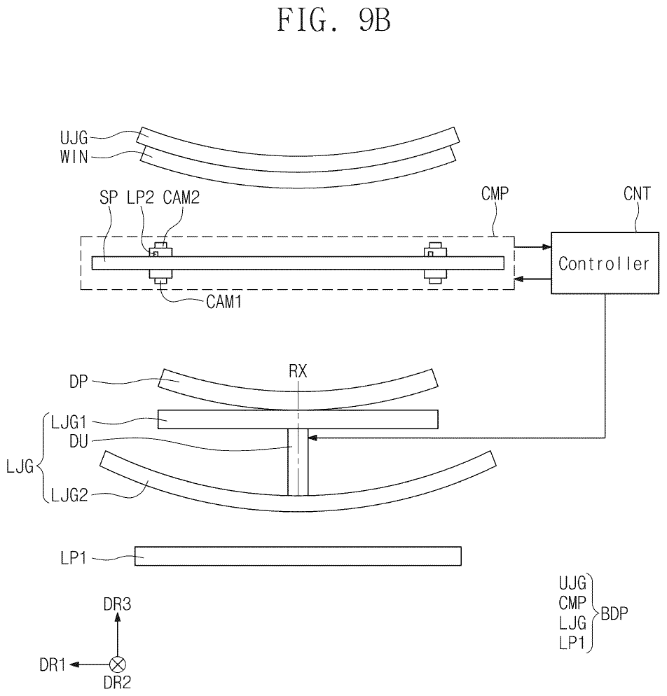

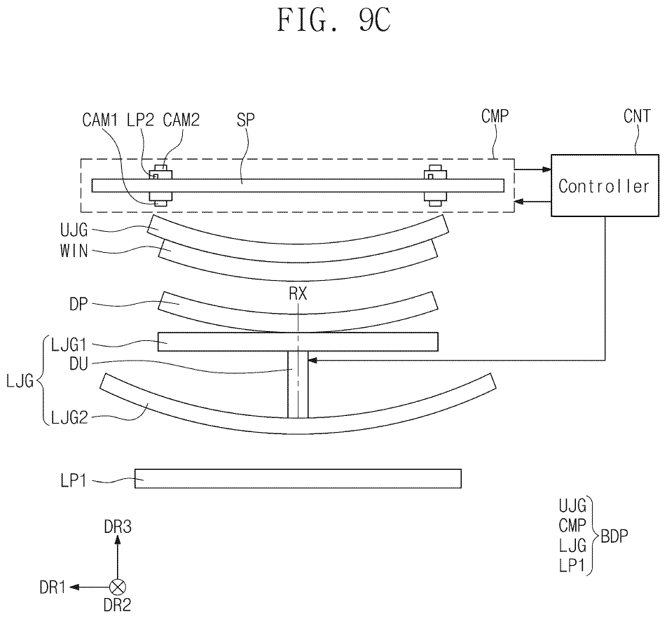

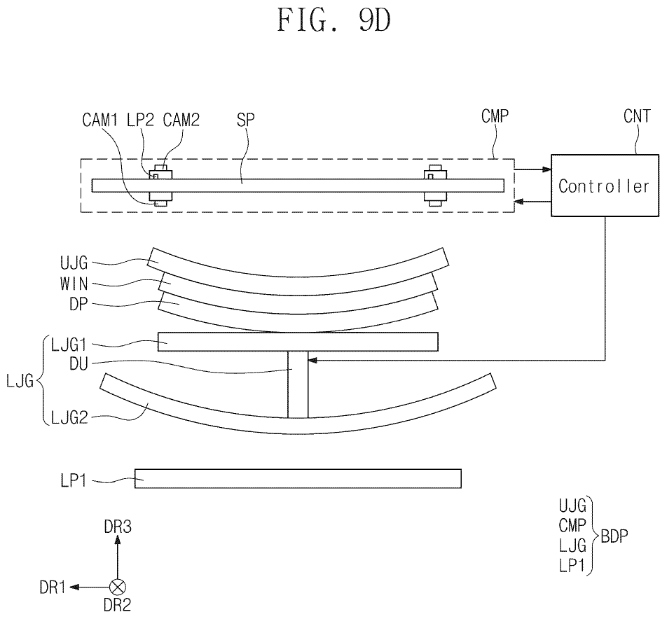

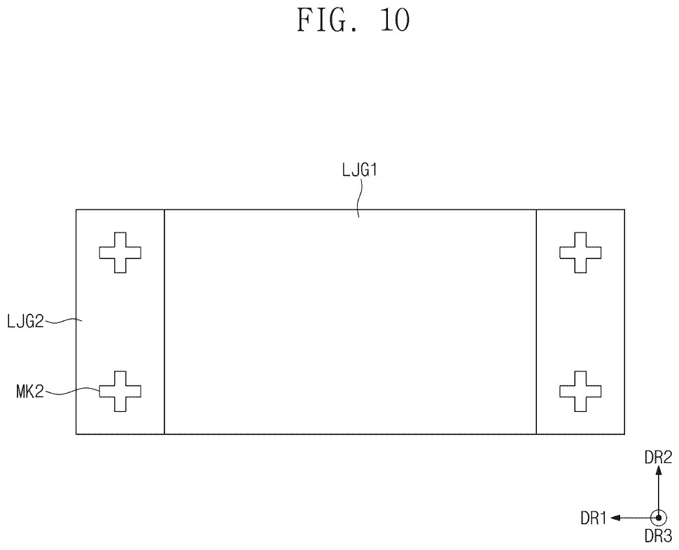

FIG. 8 is a flowchart for illustrating a method of manufacturing the display device illustrated in FIG. 1 according to an embodiment of the present disclosure. FIGS. 9A to 9D are side views illustrating a method of manufacturing a display device according to an embodiment of the present disclosure. FIG. 10 is a plan view of a first lower jig and a second lower jig illustrated in FIG. 9A.

As an example, FIGS. 9A to 9D illustrate a display panel DP, a window WIN, and an apparatus BDP for manufacturing a display device as viewed from the second direction DR2.

Among components illustrated in FIGS. 8 to 10, descriptions of components that are the same as the components explained with reference to the previous drawings may be omitted or explained briefly.

Referring to FIG. 9A, the apparatus BDP for manufacturing a display device may include an upper jig UJG, a lower jig LJG, a camera part, or camera, CMP, and a first lighting unit LP1. The upper jig UJG may be disposed above the lower jig LJG. A bottom surface of the upper jig UJG facing the lower jig LJG may have a curved surface that is convex downward. A top surface of the upper jig UJG opposed in the third direction DR3 to the bottom surface of the upper jig UJG may have a curved surface that is concave downward.

Although not illustrated, in an embodiment, a plurality of openings may be defined in the bottom surface of the upper jig UJG. When the window WIN is disposed on the bottom surface of the upper jig UJG, the openings may be in a vacuum state and thus fix the window WIN.

The first lighting unit LP1 may be disposed under the lower jig LJG. The first lighting unit LP1 may emit first light upward.

Referring to FIGS. 9A and 10, the lower jig LJG may include a first lower jig LJG1, a second lower jig LJG2, and a driving part, or driver, DU. In an embodiment, a top surface of the first lower jig LJG1 may be parallel to a plane defined by the first direction DR1 and the second direction DR2.

Although not illustrated, in an embodiment, a plurality of openings may be defined in the top surface of the first lower jig LJG1. When the display panel DP is disposed on the top surface of the first lower jig LJG1, the openings may be in a vacuum state and thus fix the display panel DP.

The second lower jig LJG2 may be disposed under the first lower jig LJG1. In an embodiment, when viewed on a plane, an area of the second lower jig LJG2 may be greater than an area of the first lower jig LJG1. When viewed on a plane, a portion of the second lower jig LJG2 may overlap the first lower jig LJG1. When viewed on a plane, borders of the second lower jig LJG2 may not overlap the first lower jig LJG1.

When viewed from the second direction DR2, the second lower jig LJG2 may be bent with respect to an axis parallel to the second direction DR2. A top surface of the second lower jig LJG2 may have a curved surface that is concave downward. A bottom surface of the second lower jig LJG2 may have a curved surface that is convex downward.

In an embodiment, the second lower jig LJG2 may include a plurality of alignment marks MK2. When viewed on a plane, the alignment marks MK2 may be spaced apart in the first direction DR1 and the second direction DR2. In an embodiment, the alignment marks MK2 may be disposed adjacent to the corners of the second lower jig LJG2. In an embodiment, when viewed on a plane, the alignment marks MK2 may have a “+” shape, but a shape of the alignment marks MK2 is not limited thereto.

When viewed on a plane, the alignment marks MK2 may not overlap the first lower jig LJG1. When viewed on a plane, the alignment marks MK2 may be disposed outside the borders of the first lower jig LJG1.

The driving part DU may be disposed between the first lower jig LJG1 and the second lower jig LJG2. The driving part DU may be rotated about a rotation axis RX parallel to the third direction DR3 upon receiving a signal from a controller CNT which is to be described later. When the driving part DU is rotated about the rotation axis RX, the first lower jig LJG1 connected to the driving part DU may be rotated about the rotation axis RX.

Referring to FIG. 9A, the camera part CMP may be disposed between the upper jig UJG and the lower jig LJG. The camera part CMP may image-capture the window WIN disposed on the bottom surface of the upper jig UJG, and the display panel DP disposed on the top surface of the first lower jig LJG1.

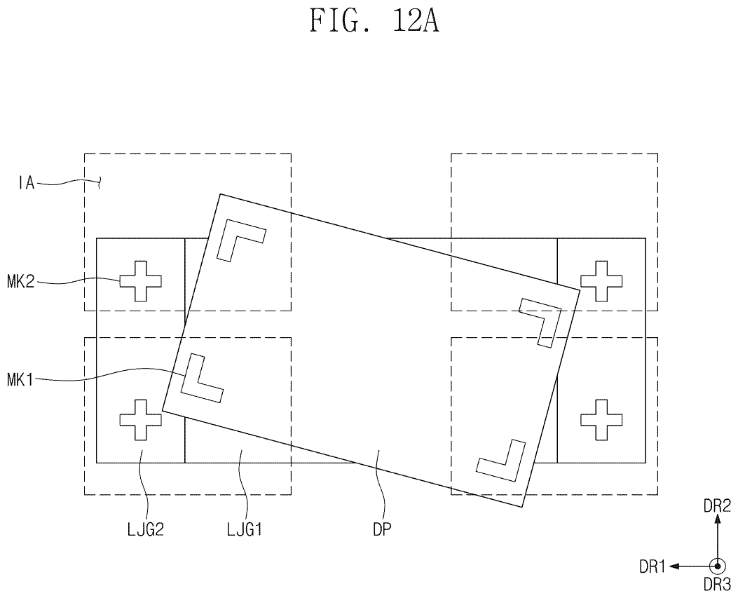

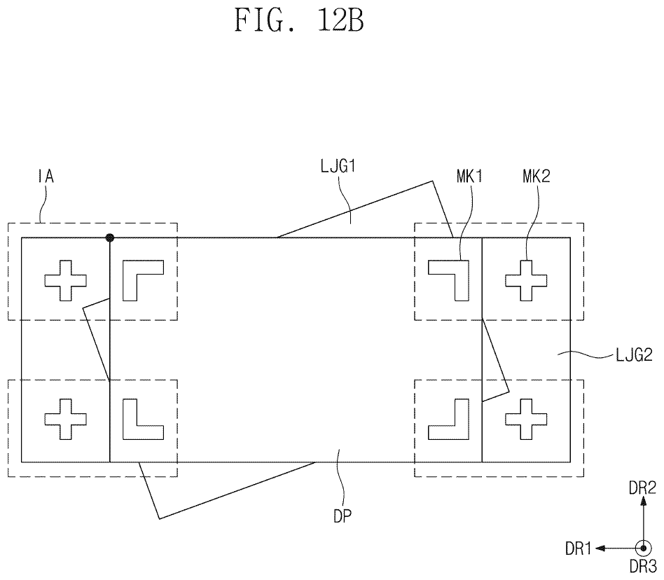

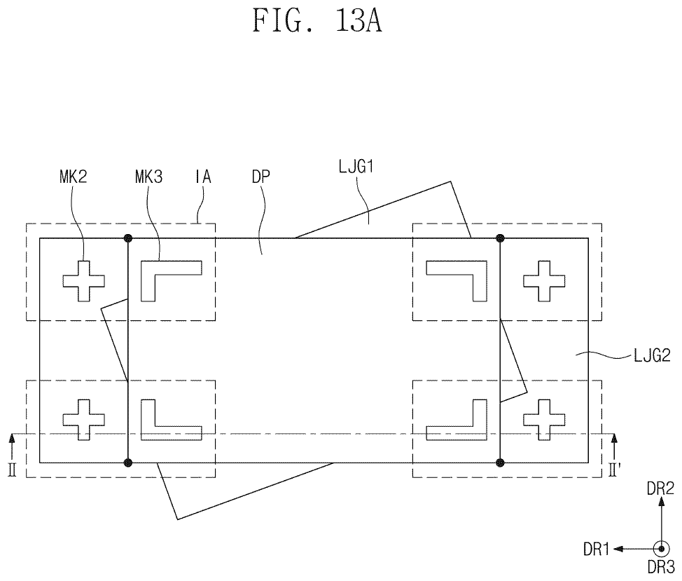

In an embodiment, the camera part CMP may include a support part SP, a plurality of first cameras CAM1 disposed on the bottom of the support part SP, and a plurality of second cameras CAM2 disposed on top of the support part SP. The first cameras CAM1 may image-capture components disposed under the first cameras CAM1. The first cameras CAM1 may image-capture a main mark MK1 (see FIG. 12A) of the display panel DP and an alignment mark MK2 (see FIG. 12A) of the second lower jig LJG2.

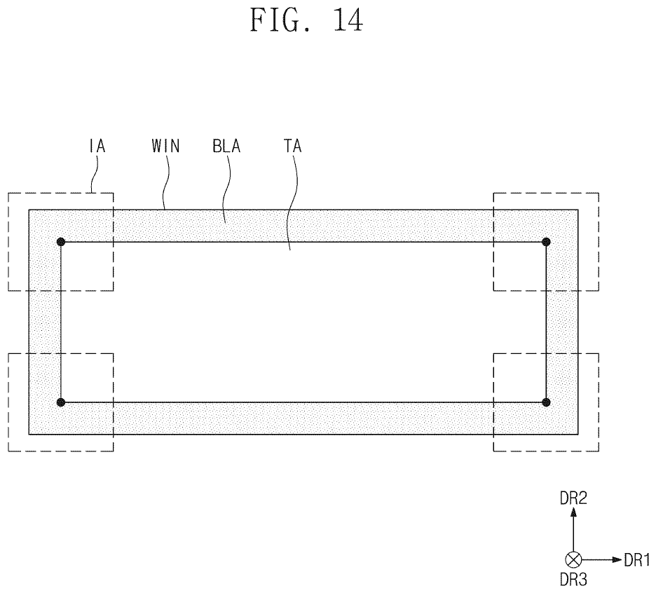

The second cameras CAM2 may image-capture the components disposed above the second cameras CAM2. The second cameras CAM2 may image-capture a boundary line between a transmission region TA and a light blocking region BLA of a window WIN, as shown in FIG. 14.

Each of the second cameras CAM2 may include a second lighting unit LP2. The second lighting unit LP2 may emit second light upward.

Images of the main marks MK1 (see FIG. 12A), images of the alignment marks MK2 (see FIG. 12A), and an image of the boundary line between the transmission region TA (see FIG. 14) and the light blocking region BLA (see FIG. 14) captured by the camera part CMP may be provided to the controller CNT. The controller CNT may acquire position information about the main marks MK1 (see FIG. 12A), position information about the alignment marks MK2 (see FIG. 12A), and position information about the boundary line between the transmission region TA (see FIG. 14) and the light blocking region BLA (see FIG. 14) of the window WIN through the images.

The controller CNT may apply a signal to the driving part DU on the basis of the position information about the main marks MK1 (see FIG. 12A) and the position information about the alignment marks MK2 (see FIG. 12A). The driving part DU, which has received the signal, may be rotated about the rotation axis RX, and may thus align the position of the display panel DP and the second lower jig LJG2. The controller CNT may apply a signal to the driving part DU on the basis of the position information about the boundary line between the transmission region TA (see FIG. 14) and the light blocking region BLA (see FIG. 14) from the camera part CMP. The driving part DU, which has received the signal, may be rotated about the rotation axis RX, and may thus align the position of the second lower jig LJG2 and the window WIN. Such an operation will be described in further detail later.

Referring to FIGS. 8 and 9A, a method of manufacturing a display device DD may include a task S100 of providing a display panel DP and a window WIN to an apparatus BDP for manufacturing a display device. The display panel DP may be disposed on the top surface of the first lower jig LJG1. The display panel DP may be disposed on the top surface of the first lower jig LJG1 in a flat state.

The window WIN may be disposed on the bottom surface of the upper jig UJG facing the lower jig LJG. The window WIN may be bent to correspond to the bottom surface of the upper jig UJG. A top surface of the window WIN facing the bottom surface of the upper jig UJG may have a curved surface that is concave downward. A bottom surface of the window WIN opposed in the third direction DR3 to the top surface of the window WIN may have a curved surface that is convex downward.

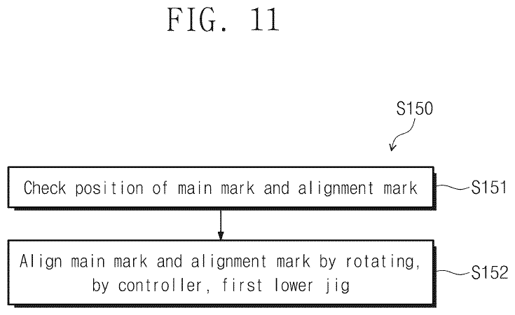

FIG. 11 is a flowchart for illustrating an alignment between a display panel and a second lower jig according to an embodiment of the present disclosure. FIGS. 12A and 12B are plan views illustrating an alignment between a display panel and a second lower jig.

Among components illustrated in FIGS. 11 to 12B, the descriptions of the components that are the same as the components explained with reference to the drawings will be omitted or explained briefly.

Referring to FIGS. 8, 11, and 12A, after a display panel DP is provided to the apparatus BDP for manufacturing a display device, a task S150 of aligning the display panel DP and a second lower jig LJG2 may be performed. The task S150 of aligning the display panel DP and the second lower jig LJG2 may include a task S151 of checking positions of a main mark MK1 and an alignment mark MK2.

As illustrated in FIG. 12A, the camera part CMP (see FIG. 9A) may image-capture the main marks MK1 and the alignment marks MK2 in inspection regions IA. Thus, the camera part CMP may acquire images of the main marks MK1 and images of the alignment marks MK2. The images of the main marks MK1 and the images of the alignment marks MK2 may be transmitted to a controller CNT (see FIG. 9A).

The controller CNT (see FIG. 9A) may acquire position information about the main marks MK1 and position information about the alignment marks MK2 on the basis of the images. As an example, the position information may be X and Y coordinates.

Referring to FIGS. 11, 12A, and 12B, the task S150 of aligning the display panel DP and the second lower jig LJG2 may include a task S152 of rotating a first lower jig LJG1. The controller CNT (see FIG. 9A) may determine whether the position information about the main marks MK1 and the position information about the alignment marks MK2 are the same as pre-set position information.

As illustrated in FIG. 12A, when the position information about the main marks MK1 and the position information about the alignment marks MK2 differ from the pre-set position information, the controller CNT may apply a signal to the driving part DU (see FIG. 9A) to adjust the positions of the main marks MK1 and the alignment marks MK2.

The driving part DU (see FIG. 9A), which has received the signal, may be rotated about a rotation axis RX (see FIG. 9A) parallel to the third direction DR3. As illustrated in FIG. 12B, when the driving part DU (see FIG. 9A) rotates about the rotation axis RX (see FIG. 9A), a first lower jig LJG1 disposed on the driving part DU (see FIG. 9A) may be rotated about the rotation axis RX (see FIG. 9A). As an example, the first lower jig LJG1 may be rotated counterclockwise. As the first lower jig LJG1 is rotated, the main marks MK1 and the alignment marks MK2 may be positioned at a pre-set position. The display panel DP and the second lower jig LJG2 may be aligned.

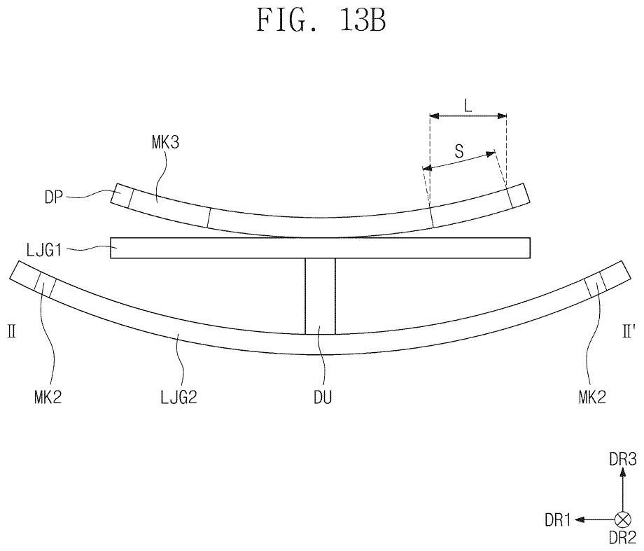

FIGS. 13A and 13B illustrate an alignment between a molded display panel and a second lower jig.

As an example, FIG. 13A illustrates a plan view of a display panel DP and a lower jig LJG, and FIG. 13B illustrates a cross-sectional view of the display panel DP and the lower jig LJG taken along the line II-II′ illustrated in FIG. 13A.

For convenience of explanation, only the lower jig LJG and the display panel DP are illustrated in FIG. 13A.

Among components illustrated in FIGS. 13A to 13B, descriptions of the components that are the same as the components explained with reference to the previous drawings may be omitted or explained briefly.

Referring to FIGS. 8 and 9B, after the display panel DP and the second lower jig LJG2 are aligned, a task S200 of molding the display panel DP may be performed. The display panel DP may be molded by an external force. When viewed from the second direction DR2, the display panel DP may have a curved shape. A top surface of the display panel DP may have a curved surface that is concave downward. A bottom surface of the display panel DP may have a curved surface that is convex downward. Here, the display panel DP may change in position while being molded, such as due to vibration or shaking.

Referring to FIGS. 13A and 13B, when the display panel DP is molded, the main marks MK1 of the display panel DP may be deformed. In an embodiment, as illustrated in FIG. 13B, the display panel DP has a curved shape, and the main marks MK1 may have a curved shape. Herein, deformation marks MK3 may be defined by the deformed main marks MK1.

After the display panel DP is molded, a task S250 of aligning the deformation mark MK3 and the alignment mark MK2 may be performed. The camera part CMP (see FIG. 9A) may acquire images of the deformation marks MK3 disposed in the inspection regions IA, and transmit the images to the controller CNT (see FIG. 9A). An actual length of a top surface of the deformation marks MK3 may be defined as a first length S. The first length S may be an arc length. The camera part CMP (see FIG. 9A), which captures images of the deformation marks MK3 on a plane, may recognize the length of the deformation marks MK3 as a chord length. As an example, the chord length of the deformation marks MK3 may be defined as a second length L.

The controller CNT (see FIG. 9A) may acquire position information about the alignment marks MK2 and the deformation marks MK3 on the basis of the second length L. The controller CNT (see FIG. 9A) may determine whether the position information about the alignment marks MK2 and the deformation marks MK3 are the same as pre-set position information.

Even when the display panel DP is molded, the camera part CMP (see FIG. 9A) and the controller CNT recognize the first length S, which is an arc length, as the second length L, which is a chord length, and acquire position information on the basis of the second length L, and, accordingly, an alignment precision between the display panel DP and the second lower jig LJG2 may be improved.

The controller CNT (see FIG. 9A) may apply a signal to the driving part DU to adjust positions of the deformation marks MK3 and the alignment marks MK2. The driving part DU and the first lower jig LJG1 may be rotated about the rotation axis RX (see FIG. 9A). Thus, the display panel DP and the second lower jig LJG2 may be aligned.

FIG. 14 is a plan view illustrating an alignment of a window.

For example, FIG. 14 is a plan view of a bottom surface of a window WIN.

Among components illustrated in FIG. 14, descriptions of the components that are the same as the components explained with reference to the previous drawings may be omitted or explained briefly.

Referring to FIGS. 8, 9B, and 14, a method for manufacturing a display device DD may include a task S300 of checking a position of the window WIN and an alignment mark MK2 of a second lower jig LJG2. In an embodiment, second cameras CAM2 may capture an image of a bottom surface of the window WIN. As illustrated in FIG. 14, the second cameras CAM2 may capture an image of a boundary line between a transmission region TA and a light blocking region BLA disposed in inspection regions IA.

The camera part CMP may transmit, to a controller CNT, the image of the boundary line between the transmission region TA and the light blocking region BLA. The controller CNT may acquire position information about the boundary line between the transmission region TA and the light blocking region BLA on the basis of the image of the boundary line between the transmission region TA and the light blocking region BLA. The controller CNT may compare position information about the alignment marks MK2 (see FIG. 13A) and the position information about the boundary line between the transmission region TA and the light blocking region BLA.

Referring to FIGS. 8 and 9C, the method of manufacturing a display device DD may include a task S350 of inspecting, by the controller CNT, an alignment between the window WIN and the display panel DP by comparing the position information about the alignment marks MK2 (see FIG. 13A) with the position information about the boundary line between the transmission region TA and the light blocking region BLA.

When the window WIN and the display panel DP are aligned at pre-set positions, a task S400 of disposing the window WIN to be adjacent to the display panel DP by moving the upper jig UJG and the window WIN downward may be performed. Although not illustrated, if the position information about the window WIN and the display panel DP differs from the pre-set position information, the first lower jig LJG1 may be rotated about the rotation axis RX.

As illustrated in FIG. 90, when the window WIN is moved downward, the position information about the window WIN may change due to vibration or shaking, for example. Thus, when the window WIN is disposed adjacent to the display panel DP, a task S450 of reinspecting, by the camera part CMP and the controller CNT, the position information about the window WIN may be performed. The position information about the window WIN may be inspected by the alignment mark MK2 (see FIG. 10). Since the position information about the window WIN is reinspected, a bonding precision between the display panel DP and the window WIN may be increased.

Referring to FIGS. 8 and 9D, in a task S500 of determining whether the position information about the window WIN and the display panel DP satisfies an error criterion, if the position information satisfies the error criterion, the display panel DP and the window WIN may be bonded, as illustrated in FIG. 9D. If the position information does not satisfy the error criterion, the display panel DP and the window WIN may be aligned by rotating the driving part DU and the first lower jig LJG1. Thus, the bonding precision between the display panel DP and the window WIN may be increased.

Although not illustrated, the window WIN and the display panel DP may be bonded together by an adhesive OCA (see FIG. 2).

According to one or more embodiments of the present disclosure, a first lower jig may be rotated to align a display panel and a second lower jig. Accordingly, even when a position and shape of a main mark are changed during molding of the display panel, the display panel and the second lower jig may be easily aligned. Thus, alignment precision of the display panel and the window may be improved.

In the above, description has been made with reference to some embodiments of the inventive concept, but those skilled in the art or those of ordinary skill in the relevant technical field will understand that various modifications and changes may be made to the inventive concept within the scope not departing from the spirit and the technology scope of the inventive concept, as described in the claims. In addition, embodiments disclosed in the present disclosure are not intended to limit the technical spirit of the inventive concept, and all technical ideas within the scope of the following claims and their equivalents are to be construed as being included in the scope of the inventive concept.

What is claimed is:

1. An apparatus for manufacturing a display device, the apparatus comprising:
a lower jig;
an upper jig above the lower jig, and comprising a bottom surface facing the lower jig and on which a window is arranged; and
a camera between the lower jig and the upper jig,
wherein the lower jig comprises
a first lower jig on which a display panel including a main mark is configured to be arranged,
a second lower jig under the first lower jig and comprising an alignment mark, and
a driver between the first lower jig and the second lower jig.

2. The apparatus of claim 1, wherein the first lower jig is parallel to a plane defined by a first direction and a second direction crossing the first direction, and
the first lower jig is rotatable by the driver about a rotation axis parallel to a third direction crossing the plane defined by the first direction and the second direction.

3. The apparatus of claim 2, wherein, when the first lower jig is rotated, the display panel arranged on the first lower jig is rotated, and
the display panel and the second lower jig are aligned.

4. The apparatus of claim 1, wherein a top surface of the second lower jig has a curved surface that is concave downward.

5. The apparatus of claim 4, wherein the bottom surface of the upper jig facing the lower jig has a curved surface that is convex downward.

6. The apparatus of claim 5, wherein a top surface of the display panel facing the bottom surface of the upper jig has a curved surface that is concave downward.

7. The apparatus of claim 1, wherein the camera comprises:
a support above the first lower jig;
a first camera below the support; and
a second camera on the support.

8. The apparatus of claim 7, further comprising a controller configured to receive, from the first camera, a first image of the main mark and the alignment mark,
wherein the controller is configured to receive a second image of the window from the second camera, and
the controller is configured to cause the first lower jig to be rotated on the basis of position information acquired from the first and the second images.

9. The apparatus of claim 1, wherein, as viewed on a plane, an area of the second lower jig is greater than an area of the first lower jig.

10. The apparatus of claim 9, wherein as viewed on the plane, the alignment mark is located outside the first lower jig.

11. A method of manufacturing a display device, the method comprising:
arranging a display panel comprising a main mark on a first lower jig parallel to a plane defined by a first direction and a second direction crossing the first direction, and arranging a window on a bottom surface of an upper jig located above the first lower jig;
aligning the main mark of the display panel and an alignment mark of a second lower jig located under the first lower jig by rotating the first lower jig about a rotation axis parallel to a third direction crossing a plane defined by the first direction and the second direction;
molding the display panel by applying an external force to the display panel such that a top surface of the display panel has a curved surface that is concave downward;
aligning the alignment mark and a deformation mark defined by the main mark of the molded display panel by rotating the first lower jig;
acquiring position information about the window and position information about the alignment mark, and aligning the window and the display panel; and
moving the window downward toward the display panel, and bonding the window and the display panel.

12. The method of claim 11, wherein the aligning of the alignment mark and the main mark comprises:
acquiring an image of the main mark and an image of the alignment mark by image-capturing, by a camera, the main mark and the alignment mark;
transmitting, to a controller, the image of the main mark and the image of the alignment mark to acquire position information about the main mark and position information about the alignment mark; and
rotating a driver about the rotation axis by applying, to the driver, a signal based on the position information about the main mark and the position information about the alignment mark,
the first lower jig coupled to the driver being rotated about the rotation axis when the driver is rotated.

13. The method of claim 11, wherein a shape of the main mark and a shape of the deformation mark are different from each other.

14. The method of claim 11, wherein a top surface of the second lower jig facing a bottom surface of the first lower jig has a shape that is concave downward.

15. The method of claim 11, wherein, as viewed on a plane, an area of the second lower jig is greater than an area of the first lower jig.

16. The method of claim 15, wherein as viewed on the plane, the alignment mark does not overlap the first lower jig.

17. The method of claim 15, wherein the alignment mark comprises a plurality of alignment marks, and
as viewed on the plane, the alignment marks are adjacent to corners of the second lower jig.

18. The method of claim 11, wherein the aligning of the window and the display panel comprises:
image-capturing, by the camera, a boundary between a transmission region and a light blocking region adjacent to the transmission region to check a position of a boundary line between the transmission region and the light blocking region; and
transmitting the position of the boundary line to a controller and causing the controller to rotate the first lower jig.

19. The method of claim 11, wherein the bonding of the window and the display panel comprises:
arranging the window to be adjacent to the display panel by moving the window downward;
aligning the alignment mark and the window adjacent to the display panel; and
moving the window downward and bonding the window to the top surface of the display panel.

20. The method of claim 11, wherein the bottom surface of the window facing the display panel has a curved surface that is convex downward.
